(19) United States
(12) Patent Application Publication
(10) Pub. No.: US 2008/0258156 A1
(43) Pub. Date: Oct. 23, 2008

(54) Light-emitting diode apparatus

(75) Inventor: Masayuki HATA, Kadoma-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 11/864,380

(22) Filed: Sep. 28, 2007

(30) Foreign Application Priority Data
Sep. 29, 2006 (JP) 2006-268825
Sep. 7, 2007 (JP) 2007-233391

(51) Int. Cl. H01L 33/00

(52) U.S. Cl. 257/88; 257/99; 257/98; 257/E33.056; 257/E33.066

(57) ABSTRACT

In a light-emitting diode apparatus, light emitted from a principal plane of an emission layer has a plurality of unequal luminous intensities depending on the in-plane azimuth angle of the principal plane of the emission layer, and at least one of a light-emitting diode chip and a package has a structure of reducing difference in the intensity of light emitted from the package according to variation in the in-plane azimuth angle of a chip-arrangement surface.

### CROSS-REFERENCE TO RELATED APPLICATIONS

The first priority application number JP2006-268825, Light-Emitting Diode Apparatus, Sep. 29, 2006, Masayuki Hata, and the second priority application number JP2007-233391, Light-Emitting Diode Apparatus, Sep. 7, 2007, Masayuki Hata, upon which this patent application is based are hereby incorporated by reference.

### BACKGROUND OF THE INVENTION

1. Field of the Invention

The present invention relates to a light-emitting diode (LED) apparatus, and more particularly it relates to an LED apparatus comprising a light-emitting diode chip.

2. Description of the Background Art

In a light-emitting diode apparatus comprising a light-emitting diode chip, it is known in general that a large piezoelectric field is formed in a direction perpendicular to a quantum well (QW) plane in a GaInN QW prepared on a GaN C plane (0001) substrate. Thus, in a case where the piezoelectric field exists in the GaInN quantum well, a quantum confined Stark effect shifting an energy level to a lower energy side, and emission probability is disadvantageously reduced since electrons and holes are pulled away and hence emission efficiency is disadvantageously reduced, as compared with a case where no electric field exists occurs.

In order to solve the disadvantages, a light-emitting diode chip in which a quantum well is formed not on a C plane (0001) but on an A plane {11-20}, an M plane {1-100} or a (2-1-14) plane, and a light-emitting diode chip having a (10-1-3) plane as a principal plane have been proposed as a device structure reducing a piezoelectric effect in gallium nitride. A light-emitting diode chip in which an InGaN/GaN multiple quantum well (MQW) having a (10-1-3) plane as a principal plane is employed as an emission layer has been proposed in general. In the aforementioned light-emitting diode chip in which the quantum well is formed on the plane {11-20}, the M plane {1-100} or the (2-1-14) plane and light-emitting diode chip having the (10-1-3) plane as the principal plane, the quantum well is formed on the plane other than the C plane, whereby the piezoelectric effect can be reduced.

In the aforementioned quantum well formed on the plane other than the C plane, however, it is reported that the oscillator strength of the emission layer has large anisotropy in the in-plane direction of the principal plane of the emission layer (quantum well). More specifically, c-axis has a six-fold rotational symmetry axis in the GaInN quantum well having the C plane as the principal plane, and hence the oscillator strengths of <11-20> polarization and <1-100> polarization are equal to each other, an oscillator strength with respect to linear polarization in the quantum well plane has no anisotropy. On the other hand, the GaInN quantum well having the plane other than the C plane as the principal plane has no rotational symmetry and hence the oscillator strength with respect to the linear polarization in the quantum well plane has anisotropy. In other words, the oscillator strength with respect to the linear polarization has a plurality of unequal magnitudes depending on directions of linear polarization in the quantum well plane. Thus, in a case where primary light emitted from the quantum well is observed in a normal direction of the well layer, the primary light is linearly polarized in the quantum well having the plane other than the C plane. For example, in a light-emitting diode chip where an MQW having a (1-10-1-3) plane as a principal plane formed by stacking well layers of Ga_{0.6}In_{0.4}N with 4 nm and barrier layers of GaN formed on a sapphire (1-100) plane is employed as an emission layer, primary light emitted from the emission layer is strongly polarized in a [11-20] direction.

It is expected in theory that primary light emitted from the light-emitting diode chip in which the quantum well having the plane other than the C plane as the principal plane has a distribution in which a luminous intensity is large in a direction perpendicular to the direction having the large oscillator strength. For example, in a conventional light-emitting diode chip, it is expected that primary light emitted from the light-emitting diode chip is strongly polarized in the [11-20] direction, and, primary light emitted in the [11-20] direction is weak, primary light emitted in a direction perpendicular to the [11-20] direction is strong. Thus, secondary light emitted from a light-emitting diode apparatus comprising the light-emitting diode chip conceivably also has large anisotropy of the luminous intensity in a case where primary light emitted from the emission layer has large anisotropy of the luminous intensity according to variation in the in-plane azimuth angle of the principal plane of the emission layer. More specifically, in a case where the light-emitting diode apparatus comprises the light-emitting diode chip and a package having a chip-arrangement surface parallel to a principal plane (light-emission surface) of the light-emitting diode chip, on which the light-emitting diode chip is arranged, secondary light emitted from the light-emitting diode apparatus generally has large anisotropy of the luminous intensity relative to the in-plane azimuth angle of the chip-arrangement surface of the package. Thus, it is disadvantageously difficult to reduce difference in the luminous intensity of secondary light emitted from the package according to variation in the in-plane azimuth angle of the chip-arrangement surface. In this case, the light-emitting diode apparatus can not be disadvantageously used for, for example, a illumination lamp or an indicating lamp requiring uniformity of the luminous intensity of secondary light relative to the in-plane azimuth angle of the chip-arrangement surface of the package.

### SUMMARY OF THE INVENTION

A light-emitting diode apparatus according to an aspect of the present invention comprises a light-emitting diode chip including an emission layer having a principal plane, and a package having a chip-arrangement surface on which the light-emitting diode chip is arranged, wherein primary light emitted from the principal plane of the emission layer has a plurality of unequal luminous intensities depending on the in-plane azimuth angle of the principal plane of the emission layer, and at least one of the light-emitting diode chip and the package has a structure of reducing difference in the intensity of secondary light emitted from the package according to variation in the in-plane azimuth angle of the chip-arrangement surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view for illustrating a light-emitting diode chip employed in the present invention;

FIG. 2 is a diagram showing the relation between a direction defined by a polar angle θ and an azimuth angle φ and crystal orientations of an emission layer having a (11-20) plane as a principal plane and an in-plane of the emission layer;

FIG. 3 is a diagram showing the relation between azimuth angles φ and the luminous intensity of light emitted in a direction inclined by a finite angle θ (other than 0) with respect to a [11-20] direction from a quantum well emission layer in which GaInN having a (11-20) plane as a principal plane is employed as a well layer;

FIG. 4 is a plan view showing a structure of a light-emitting diode apparatus according to a first embodiment of the present invention;

FIG. 5 is a sectional view showing the structure of the light-emitting diode apparatus according to the first embodiment shown in FIG. 4;

FIG. 6 is a plan view showing a structure of a support member of the light-emitting diode apparatus according to the first embodiment shown in FIG. 4;

FIG. 7 is a plan view showing a structure of a light-emitting diode apparatus according to a modification of the first embodiment of the present invention;

FIG. 8 is a plan view showing a structure of a light-emitting diode apparatus according to a second embodiment of the present invention;

FIG. 9 is a sectional view showing the structure of the light-emitting diode apparatus according to the second embodiment shown in FIG. 8.

FIG. 10 is a plan view showing a structure of a light-emitting diode apparatus according to a third embodiment of the present invention;

FIG. 11 is a sectional view showing the structure of the light-emitting diode apparatus according to the third embodiment shown in FIG. 10;

FIG. 12 is a sectional view showing a structure of a light-emitting diode apparatus according to a fourth embodiment of the present invention;

FIG. 13 is a plan view showing a structure of a light-emitting diode apparatus according to a fifth embodiment of the present invention;

FIG. 14 is a sectional view taken along the line 200-200 in FIG. 13;

FIG. 15 is a sectional view taken along the line 300-300 in FIG. 13;

FIG. 16 is a diagram showing a state of refracting light emitted from a package according to the fifth embodiment shown in FIG. 13 toward a [0001] direction and a [000-1] direction;

FIG. 17 is a plan view showing a structure of a light-emitting diode apparatus according to a first modification of the fifth embodiment of the present invention;

FIG. 18 is a sectional view taken along the line 400-400 in FIG. 17;

FIG. 19 is a sectional view taken along the line 500-500 in FIG. 17;

FIG. 20 is a plan view showing a structure of a light-emitting diode apparatus according to a second modification of the fifth embodiment of the present invention; and

FIG. 21 is a plan view showing a structure of a light-emitting diode apparatus according to a third modification of the fifth embodiment of the present invention.

### DESCRIPTION OF THE PREFERRED EMBODIMENTS

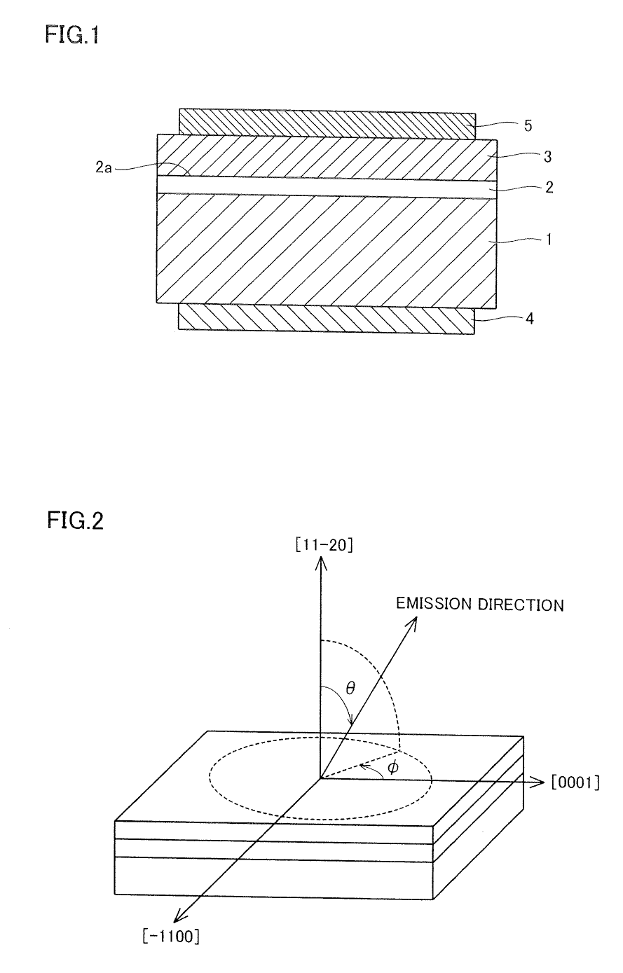

A schematic structure of a light-emitting diode chip employed in the present invention will be described with reference to FIG. 1 prior to a description of specific embodiments of the present invention.

In the light-emitting diode chip employed in the present invention, an emission layer 2 is formed on a first semiconductor 1 as shown in FIG. 1. A second semiconductor 3 is formed on the emission layer 2. A first electrode 4 is formed on a lower surface of the first semiconductor 1 and a second electrode 5 is formed on the second semiconductor 3.

In the light-emitting diode chip employed in the present invention, a material of the light-emitting diode chip and a direction of a principal plane are selected such that the luminous intensity of primary light emitted from the emission layer 2 has anisotropy relative to the in-plane azimuth angle of a principal plane (upper surface) 2a of the emission layer 2. For example, in a case of a semiconductor having a wurtzite structure, 4H-SiC or 6H-SiC, the principal plane is selected to be a plane other than a (0001) plane. In this case, when a (H,K,−H−K,0) plane such as a (11-20) plane and a (1-100) plane is the principal plane, the anisotropy of the luminous intensity relative to the in-plane azimuth angle of the principal plane is the strongest.

Alternatively, for example, a {11-24} plane, a {11-22} plane, a {1-101} plane, a {1-102} plane and a {1-103} plane or a (H,K,−H−K,L) plane (L is not 0) such as a plane misoriented by a prescribed angle range from these planes may be the principal plane, or the plane misoriented by the prescribed angle range from these planes may be the principal plane A nitride-based semiconductor such as AlGaN, GaN and GaInN having the wurtzite structure, a hexagonal crystal such as 2H—SiC, 4H—SiC and 6H—SiC, α-SiC having a rhombohedron structure, MgZnO, ZnCdO and ZnS having the wurtzite structure or the like is employed as a specific material. In a case of employing a semiconductor having a zincblende structure, the principal plane must be a plane other than a {001} plane and a {111} plane ({110} plane, for example) and the emission layer must have a quantum well structure.

Generally, when a double heterostructure is prepared by forming the emission layer 2 having a smaller band gap than band gaps of the first semiconductor 1 and the second semiconductor 3, carriers can be easily confined in the emission layer 2 and emission efficiency can be improved. When the emission layer 2 has a single quantum well structure or a MQW structure, the emission efficiency can be further improved. In a case of this quantum well structure, the thickness of a well layer is small and hence crystallinity of the well layer can be inhibited from being deteriorated also when the well layer has strain. Also when the well layer has compressive strain in the in-plane direction of the principal plane 2a of the emission layer or has tensile strain in the in-plane direction, crystallinity is inhibited from being deteriorated. The emission layer 2 may be undoped or doped.

According to the present invention, the first semiconductor 1 may be constituted by a substrate or a semiconductor layer, or may be constituted by both of the substrate and the semiconductor layer. In a case where the first semiconductor 1 is constituted by both of the substrate and the semiconductor layer, the substrate is formed on a side opposite to a side on which the second semiconductor 3 of the first semiconductor 1 is formed (lower side). The substrate may be a growth substrate, or may be a support substrate bonded to a growth surface of the semiconductor layer for supporting the semiconductor layer after growing the semiconductor layer.

In a light-emitting diode chip of p-n junction type, the first semiconductor 1 and the second semiconductor 3 have different conductivity from each other. The first semiconductor 1 may be a p-type semiconductor and the second semiconductor 3 may be an n-type semiconductor, or the first semiconductor 1 may be the n-type semiconductor or the second semiconductor 3 may be the p-type semiconductor.

The first semiconductor 1 and the second semiconductor 3 each may include a cladding layer (not shown) having a larger band gap than the emission layer 2, and the like. Alternatively, the first semiconductor 1 and the second semiconductor 3 each may include the cladding layer and a contact layer (not shown) from a side of the emission layer 2. In this case, the contact layer preferably has a smaller band gap than the cladding layer.

In a case of employing the nitride-based semiconductor having the wurtzite structure, a nitride-based semiconductor substrate of AlN, GaN, AlGaN or GaInN, or a substrate other than the nitride-based semiconductor such as a sapphire substrate, a spinel substrate, a Si substrate, a GaAs substrate, a GaP substrate and a ZrB₂ substrate can be employed as the substrate. In the emission layer of the quantum well, GaInN can be employed as the well layer, and AlGaN, GaN or GaInN having a lager band gap than the well layer can be employed as a barrier layer. As the cladding layer and the contact layer, GaN or AlGaN may be employed.

The second electrode 5 may be formed partially on the second semiconductor 3. The electrode formed on a light-emission side (upper side) of the light-emitting diode chip (second electrode 5 here) preferably has light transmittance.

The principal plane 2a of the emission layer 2 is arranged parallel to a chip-arrangement surface of the package (not shown), as described later.

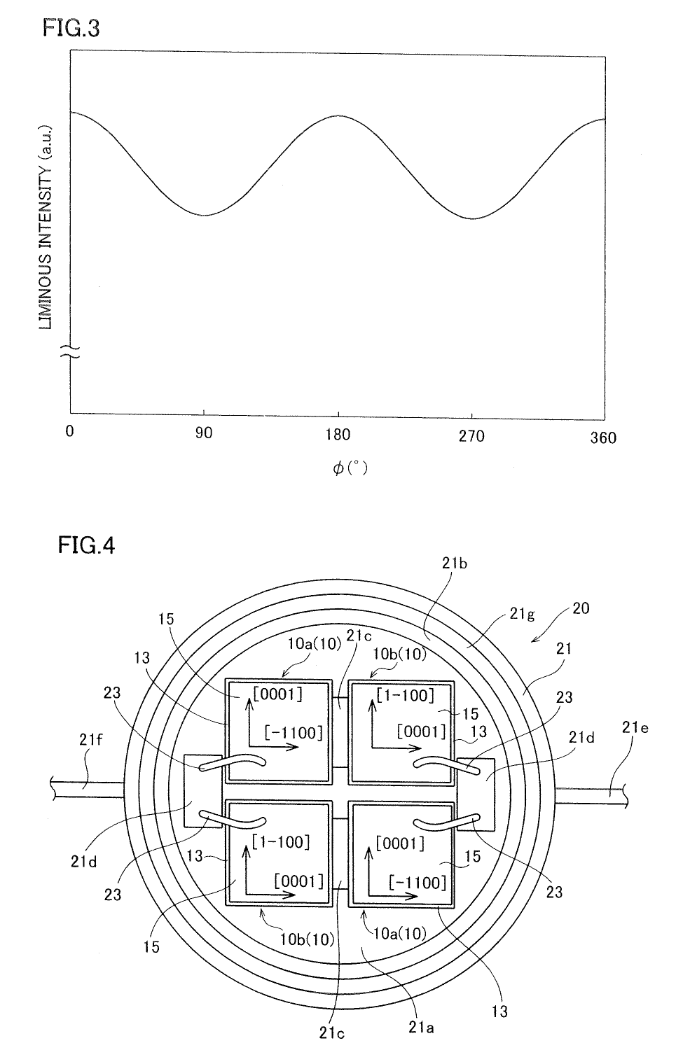

The anisotropy of the luminous intensity relative to the in-plane azimuth angle of the principal plane will be now described citing a light-emitting diode having a quantum well emission layer where GaInN having a (H,K,−H−K,0) plane as a principal plane is employed as a well layer. As shown in FIGS. 2 and 3, φ=0°, 90°, 180° and 270° coincide with a [0001] direction, a [1-100] direction, a [000-1] direction and a [−1100] direction of the emission layer respectively. As shown in FIG. 3, primary light emitted in a direction inclined by a finite polar angle θ has the anisotropy of the luminous intensity relative to the in-plane azimuth angle of the principal plane 2a of the emission layer 2, and the luminous intensity is large in a direction of an azimuth angle of φ=0° or 180° while the luminous intensity is small in a direction of an azimuth angle of φ=90° or 270°. The light-emitting diode having the principal plane of the (11-20) plane is illustrated in FIG. 3. On the other hand, in a light-emitting diode having a quantum well emission layer where GaInN having a (H,K,−H−K,0) plane as a principal plane is employed as a well layer, the luminous intensity is large in a direction of an azimuth angle of the [0001] direction while the luminous intensity is small in a direction of an azimuth angle of a [K,−H,H−K,0] direction, and the azimuth angles in the direction of the large luminous intensity and the small luminous intensity differ by 90°. The luminous intensity shows the property of two-fold rotational symmetry in the in-plane of the principal plane of the emission layer 2.

### First Embodiment

A structure of a light-emitting diode apparatus according to a first embodiment will be now described with reference to FIGS. 4 to 6.

As shown in FIGS. 4 and 5, the light-emitting diode apparatus according to the first embodiment includes four light-emitting diode chips 10 and a package 20 in which the four light-emitting diode chips 10 are arranged.

Each light-emitting diode chip 10 is constituted by a wurtzite structure nitride-based semiconductor having a (11-20) plane as a principal plane. As shown in FIG. 4, outer shapes of the light-emitting diode chips 10 each include a square shape, a rectangular shape, a rhombus shape or a parallelogram shape or the like as viewed from an upper surface side.

In each light-emitting diode chip 10, an emission layer 12 consisting of an MQW formed by stacking well layers (not shown) of Ga_{0.7}In_{0.3}N having a thickness of about 2 nm and barrier layers (not shown) of Ga_{0.9}In_{0.1}N is formed on an n-type GaN substrate 11 having a thickness of about 100 μm, as shown in FIG. 5. A p-type GaN layer 13 is formed on each emission layer 12. An n-side electrode 14 is formed on a lower surface of each n-type GaN substrate 11 and a light-transmitting p-side electrode 15 is formed on each p-type GaN layer 13.

According to the first embodiment, as to oscillator strength of the emission layer 12 of each light-emitting diode chip 10, oscillator strength with respect to [1-100]-polarized primary light is larger than that with respect to [0001]-polarized primary light. Therefore, as to a luminous intensity from each emission layer 12, primary light in a direction of an azimuth angle approximately parallel to a [0001] direction has a larger luminous intensity than primary light in a direction of an azimuth angle parallel to a [1-100] direction.

According to the first embodiment, the four light-emitting diode chips 10 are arranged on a chip-arrangement surface 21a such that principal planes 12a of the emission layers 12 are parallel to a chip-arrangement surface 21a of an after-mentioned support member 21 of the package 20.

According to the first embodiment, the two first light-emitting diode chips 10a and the two second light-emitting diode chips 10b among the four light-emitting diode chips 10 are arranged such that the [0001] directions of the first light-emitting diode chips 10a and the [1-100] directions of the second light-emitting diode chips 10b are substantially parallel to each other, as shown in FIG. 4. Therefore, the first light-emitting diode chips 10a and the second light-emitting diode chips 10b are arranged such that directions of azimuth angles having large luminous intensities in in-plane directions of the emission layers 12 of the first light-emitting diode chips 10a and directions having large luminous intensities in in-plane directions of the emission layers 12 of the second light-emitting diode chips 10b are directed to different directions from each other (directions intersecting with each other (perpendicular to each other)) in an in-plane of the package 20, and hence difference in the intensity (anisotropy of intensity) of secondary light emitted from the package 20 according to the variation in the in-plane azimuth angle of the chip-arrangement surface 21a of the support member 21 is reduced. The light-emitting diode chip 10a is an example of the “first light-emitting diode chip” in the present invention, and the light-emitting diode chip 10b is an example of the “second light-emitting diode chip” in the present invention.

As shown in FIG. 5, the package 20 is constituted by the aforementioned support member 21 and a light-transmitting molding resin 22. This support member 21 is made of an insulating material such as resin or ceramics. The support member 21 is formed with a recess portion having the aforementioned chip-arrangement surface 21a formed by a plane surface on which the light-emitting diode chips 10 are arranged and a reflective side surface 21b arranged on an outer circumferential portion of the chip-arrangement surface 21a and inclined with respect to the chip-arrangement surface 21a.

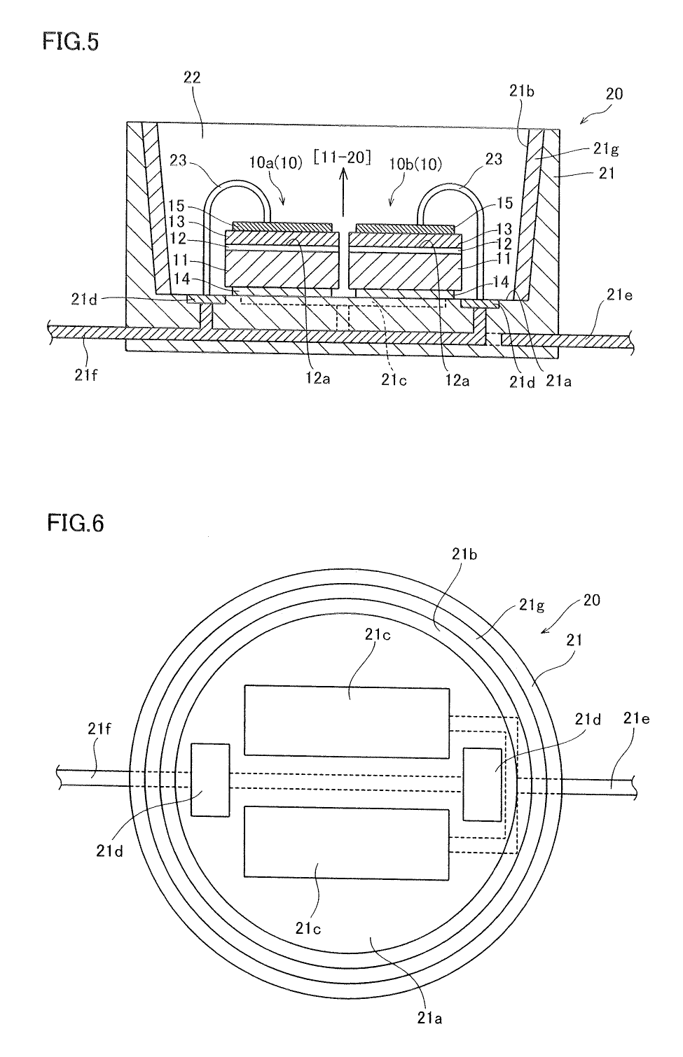

As shown in FIGS. 5 and 6, the chip-arrangement surface 21a is formed with first electrodes 21c of copper arranged in the vicinity of a central portion of the chip-arrangement surface 21a and a second electrodes 21d of copper arranged in the vicinity of a peripheral portion of the chip-arrangement surface 21a. The n-side electrodes 14 (see FIG. 5) of the light-emitting diode chips 10 are bonded on the first electrodes 21c. Wires 23 (see FIG. 5) connected to the p-side electrodes 15 (see FIG. 5) of the light-emitting diode chips 10 are connected on the second electrodes 21d. A first lead electrode 21e is connected to the first electrodes 21c, and a second lead electrode 21f is connected to the second electrodes 21d. These first and second lead electrodes 21e and 21f are so arranged as to connect inside and outside of the support member 21. Thus, the four light-emitting diode chips 10 are so wired as to always simultaneously light up.

The reflective side surface 21b is formed with a reflective material 21g of Al, Ag or the like. As shown in FIG. 6, the reflective side surface 21b is formed in a circular shape as viewed from light-emission direction (upper side) of the package.

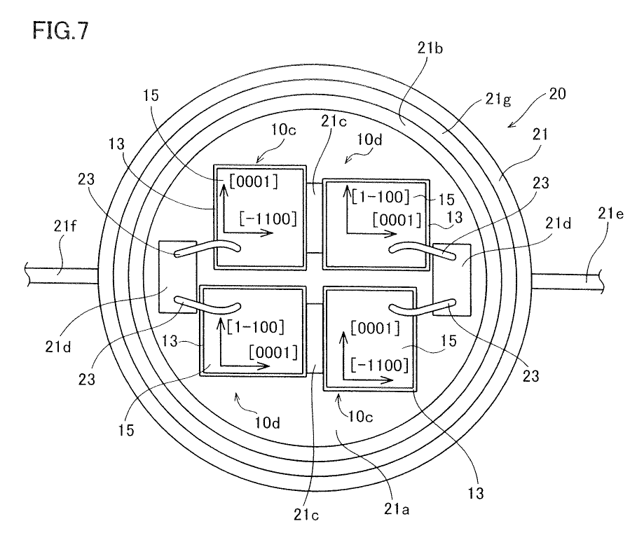

In a light-emitting diode apparatus according to a modification of the first embodiment of the present invention, upper surfaces of light-emitting diode chips 10c and 10d each have an outer shape formed in a rectangular shape having a long side substantially parallel to a [0001] direction as shown in FIG. 7, dissimilarly to the aforementioned first embodiment. According to this modification, principal planes of the light-emitting diode chips 10c and 10d each are formed in a rectangular shape of two-fold rotational symmetry in which a direction of a long side or a short side coincides with a direction having the largest luminous intensity, and hence directions having the largest luminous intensities and directions having the smallest luminous intensities relative to in-plane azimuth angles of the principal planes of the light-emitting diode chips 10c and 10d can be distinguished. Therefore, when the light-emitting diode chips 10c and 10d are arranged on a chip-arrangement surface 21a, the directions having the largest luminous intensities of the light-emitting diode chips 10c and 10d are easily recognized. A method of distinguishing between the directions having the largest luminous intensities and the directions having the smallest luminous intensities relative to the azimuth angles of the in-planes of the principal planes is not restricted to forming rectangular chips, but the method may be employed so far as the light-emitting diode chips 10c and 10d are formed such that the directions having the largest luminous intensities and the directions having the smallest luminous intensities relative to the azimuth angles of the in-planes of the principal planes of the light-emitting diode chips 10c and 10d can be distinguished. For example, marks capable of recognizing the directions having the largest luminous intensities may be formed on surfaces of the light-emitting diode chips 10c and 10d. Alternatively, in a case where the light-emitting diode chips 10c and 10d are formed with electrodes, the directions having the largest luminous intensities may be recognized by shapes or arrangement of the electrodes. The electrodes each may be alternatively formed in the rectangular shape of the two-fold rotational symmetry in which the direction of the long side or the short side coincides with the direction having the largest luminous intensity. The light-emitting diode chips 10c and 10d each may be alternatively formed in an outer shape capable of recognizing the direction having the largest luminous intensity.

### Second Embodiment

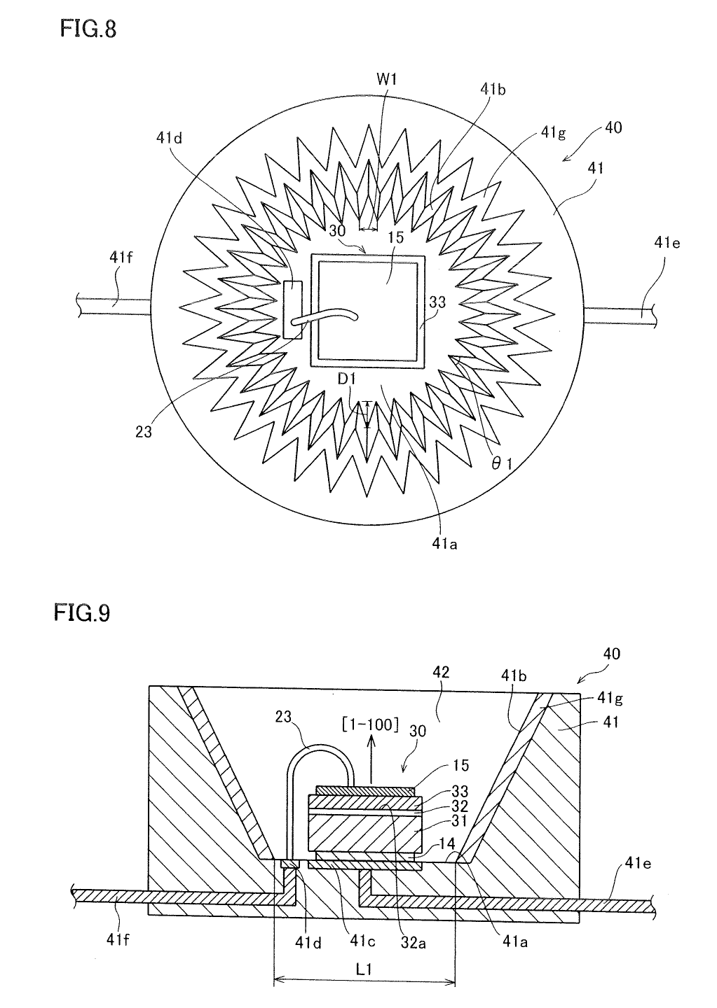

Referring to FIGS. 8 and 9, a reflective side surface of a package is formed with a shape reducing difference in the intensity of secondary light emitted from the package according to variation in the in-plane azimuth angle of a chip-arrangement surface in a light-emitting diode apparatus according to a second embodiment, dissimilarly to the light-emitting diode apparatus according to the first embodiment.

The light-emitting diode apparatus according to the second embodiment includes one light-emitting diode chip 30 and a package 40 in which the one light-emitting diode chip 30 is arranged, as shown in FIGS. 8 and 9.

The light-emitting diode chip 30 is constituted by a wurtzite structure nitride-based semiconductor having a (1-100) plane as a principal plane. As shown in FIG. 8, the light-emitting diode chip 30 is formed in a square shape having a size of about 300 μm×about 300 μm as viewed from an upper surface side.

In the light-emitting diode chip 30, an emission layer 32 consisting of an MQW formed by stacking well layers (not shown) of Ga_{0.7}In_{0.3}N having a thickness of about 2 nm and barrier layers (not shown) of Ga_{0.9}In_{0.1}N is formed on an n-type GaN layer 31, as shown in FIG. 9. A p-type GaN layer 33 is formed on the emission layer 32. An n-side electrode 14 is formed on a lower surface of the n-type GaN layer 31 and a light-transmitting p-side electrode 15 is formed on the p-type GaN layer 33 similarly to the aforementioned first embodiment.

According to the second embodiment, the luminous intensity of primary light emitted from the emission layer 32 has anisotropy relative to the in-plane azimuth angle of a principal plane (upper surface) 32a of the emission layer 32 similarly to the aforementioned first embodiment. In other words, as to the luminous intensity of primary light emitted from the emission layer 32, primary light in a direction of an azimuth angle approximately parallel to a [0001] direction has a larger luminous intensity than primary light in a direction of an azimuth angle parallel to a [11-20] direction.

As shown in FIG. 8, the package 40 is constituted by a support member 41 and a light-transmitting molding resin 42. The support member 41 is formed with a recess portion having a chip-arrangement surface 41a formed by a plane surface on which the light-emitting diode chip 30 is arranged and a reflective side surface 41b arranged on an outer circumferential portion of the chip-arrangement surface 41a and inclined with respect to the chip-arrangement surface 41a. The reflective side surface 41b is an example of the “reflective surface” in the present invention.

As shown in FIG. 9, the chip-arrangement surface 41a is formed with first electrodes 41c of copper arranged in the vicinity of a central portion of the chip-arrangement surface 41a and second electrodes 41d of copper arranged in the vicinity of a peripheral portion of the chip-arrangement surface 41a. A first lead electrode 41e is connected to the first electrodes 41c, and a second lead electrode 41f is connected to the second electrodes 41d.

According to the second embodiment, the reflective side surface 41b is formed with a reflective material 41g of Al, Ag or the like. The reflective surface 41b is formed by forming a corrugated shape on a surface of the recess portion of the support member 41 and forming the reflective material 41g on the surface of the recess portion of the support member 41. As shown in FIG. 8, the reflective side surface 41b is formed with the reflective material 41g having an corrugated shape reflecting the corrugated shape of the surface of the recess portion of the support member 41 as viewed from a light-emission direction (upper side) of the package. More specifically, reflective side surface 41b has an inner diameter L1 of about 1 mm in the vicinity of the chip-arrangement surface 41a as shown in FIG. 9. As shown in FIG. 8, an interval W1 between a projection portion and another projection portion adjacent thereto of the corrugated shape formed on the reflective side surface 41b is about 20 μm, a depth D1 of each recess portion is about 20 μm, and an angle θ1 of an apex of each projection portion is about 50°. Thus, primary light emitted from the light-emitting diode chip 30 is scattered with the reflective side surface 41b. The recess portions and the projection portions of the corrugated shape each may have a size similar to or larger than an emission wavelength. For example, the interval W1 between the projection portion and another projection portion adjacent thereto is preferably not less than about 250 nm.

The remaining structure of the second embodiment is similar to that of the aforementioned first embodiment.

According to the second embodiment, as hereinabove described, the reflective side surface 41b is formed with the corrugated shape as viewed from the light-emission direction (upper side) of the package, whereby the primary light emitted from the light-emitting diode chip 30 can be scattered with the reflective side surface 41b. Therefore, also in a case where primary light emitted from the principal plane 32a of the emission layer 32 has a plurality of unequal luminous intensities depending on the in-plane azimuth angle of the principal plane 32a of the emission layer 32, the difference in the luminous intensity of the secondary light emitted from the package 40 according to variation in the in-plane azimuth angle of the chip-arrangement surface 41a of the support member 41 can be reduced.

The remaining effects of the second embodiment are similar to those of the aforementioned first embodiment.

### Third Embodiment

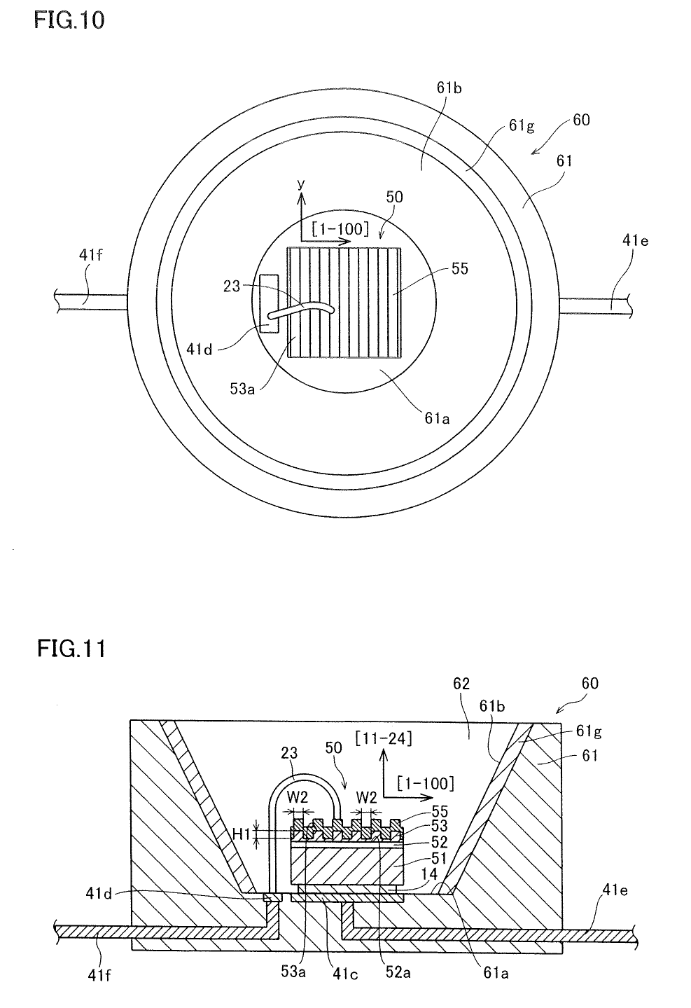

Referring to FIGS. 10 and 11, a corrugatedly shaped portion extending in a prescribed direction is formed on a light-emission surface (upper surface) of a light-emitting diode chip according to a third embodiment in order to reduce difference in the luminous intensity of secondary light emitted from a package (light-emitting diode chip).

The light-emitting diode apparatus according to the third embodiment includes one light-emitting diode chip 50 and a package 60 in which the one light-emitting diode chip 50 is arranged, as shown in FIGS. 10 and 11.

The light-emitting diode chip 50 is constituted by a wurtzite structure nitride-based semiconductor having a (11-24) plane as a principal plane. In the light-emitting diode chip 50, an emission layer 52 consisting of an MQW formed by stacking well layers (not shown) of Ga_{0.7}In_{0.3}N having a thickness of about 2 nm and barrier layers (not shown) of Ga_{0.9}In_{0.1}N is formed on an n-type GaN layer 51, as shown in FIG. 11. A p-type GaN layer 53 is formed on the emission layer 52. The p-type GaN layer 53 is an example of the “semiconductor layer” in the present invention. An n-side electrode 14 is formed on a lower surface of the n-type GaN layer 51 and a light-transmitting p-side electrode 55 is formed on the p-type GaN layer 53 similarly to the aforementioned first embodiment. The p-side electrode 55 is an example of the “electrode” in the present invention.

According to the third embodiment, the luminous intensity of primary light emitted from the emission layer 52 has anisotropy relative to the in-plane azimuth angle of a principal plane (upper surface) 52a of the emission layer 2 similarly to the aforementioned first embodiment. In other words, as to the luminous intensity of the primary light emitted from the emission layer 52, primary light in a direction of an azimuth angle approximately parallel to a direction y perpendicular to a [1-100] direction (see FIG. 10) has a larger luminous intensity than primary light in a direction of an azimuth angle parallel to the [1-100] direction. The [1-100] direction and the [−1100] direction each are an example of the “first direction” in the present invention, and the direction y is an example of the “second direction” in the present invention.

According to the third embodiment, a light-emission surface (upper surface) 53a of the p-type GaN layer 53 arranged on a light-emission surface side of the light-emitting diode chip 50 is formed with a corrugatedly shaped portion as shown in FIGS. 10 and 11. More specifically, as shown in FIG. 11, recess portions and projection portions of the corrugated shape of the light-emission surface (upper surface) 53a of the p-type GaN layer 53 each are so formed as to have a W2 width of about 0.5 μm and a height H1 of about 0.25 μm. The recess portions and the projection portions of the corrugated shape of the light-emission surface (upper surface) 53a of the p-type GaN layer 53 are so formed as to extend in the direction y. Thus, the amount of primary light emitted in the direction of the azimuth angle parallel to the [1-100] direction among primary light emitted from the light-emitting diode chip 50 can be increased. The p-side electrode 55 is corrugated along the corrugated shape of the p-type GaN layer 53. Thus, difference in the luminous intensity of secondary light emitted from the package 60 according to variation in the in-plane azimuth angles of a chip-arrangement surface 61a of a support member 61 can be reduced, in a case where primary light emitted from the emission layer 52 has a small luminous intensity in a direction of an azimuth angle of the [1-100] direction.

The recess portions and the projection portions of the corrugated shape of the p-type GaN layer 53 each may have a size similar to or larger than an emission wavelength. In a case where the emission wavelength is about 500 nm, a width W2 of each recess portion is preferably not less than about 250 nm for example.

In a case where the recess portions and the projection portions of the corrugated shape of the p-type GaN layer 53 each have a size several times the emission wavelength (about 250 nm to about 1200 nm, for example), primary light not emitted outside the light-emitting diode chip 50 by total reflection when the light-emission surface (upper surface) 53a of the p-type GaN layer 53 is a plane surface is effectively emitted outside with a diffraction effect.

In a case where the recess portions and the projection portions of the corrugated shape of the p-type GaN layer 53 each have a size larger than the emission wavelength (about 2 μm to about 50 μm, for example), the primary light emitted from the emission layer 52 is easily incident on the corrugatedly shaped portion of the p-type GaN layer 53 at not more than a critical angle and hence the primary light emitted outside the light-emitting diode chip 50 can be effectively increased.

While the corrugatedly shaped portion is formed on the light-emission surface (upper surface) 53a of the p-type GaN layer 53 in the third embodiment, a dielectric film such as TiO₂ may be formed on the p-type GaN layer 53 on the light-emission surface side and formed with the corrugatedly shaped portion. Also in a case where the corrugatedly shaped portion is formed on a lower surface of the n-type GaN layer 51 on a side opposite to the emission surface (lower side), similar effects are obtained, however, the case of forming the recess and projection portions on the emission surface side is more effective.

As shown in FIG. 11, the package 60 is constituted by the support member 61 and a light-transmitting molding resin 62 similarly to the aforementioned first embodiment. This support member 61 is formed with a recess portion having the chip-arrangement surface 61a formed by a plane surface on which the light-emitting diode chip 50 is arranged and a reflective side surface 61b arranged on an outer circumferential portion of the chip-arrangement surface 61a and inclined with respect to the chip-arrangement surface 61a.

The chip-arrangement surface 61a is formed with a first electrode 41c of copper arranged in the vicinity of a central portion of the chip-arrangement surface 61a and a second electrode 41d of copper arranged in the vicinity of a peripheral portion of the chip-arrangement surface 61a, similarly to the aforementioned second embodiment A first lead electrode 41e is connected to the first electrode 41c, and a second lead electrode 41f is connected to the second electrode 41d.

According to the third embodiment, the reflective side surface 61b is formed with a reflective material 61g of Al, Ag or the like, similarly to the aforementioned first embodiment.

The remaining structure of the third embodiment is similar to that of the aforementioned first embodiment.

The remaining effects of the third embodiment is similar to those of the aforementioned first embodiment.

The corrugatedly shaped portion extending in the prescribed direction is formed on the light-emission surface of the light-emitting diode chip 50 so as to reduce the difference in the intensity of the secondary light emitted from the package 60 according to the variation in the in-plane azimuth angle of the chip-arrangement surface 61a in the third embodiment, the present invention is not restricted to this but an alternate may be employed so far as anisotropic structure relative to the in-plane direction of the emission layer 52 is formed on the light-emission surface of the light-emitting diode chip 50. For example, elliptical shaped projection portions or recess portions as viewed from an upper surface may be formed on the light-emission surface.

### Fourth Embodiment

In a light-emitting diode apparatus according to a fourth embodiment, a package is formed with an anisotropic shaped portion relative to the in-plane direction of an emission layer as a shape of the package for reducing difference in the intensity of primary light emitted according to variation in the in-plane azimuth angle of a chip-arrangement surface dissimilarly to the aforementioned second embodiment. More specifically, a corrugatedly shaped portion extending in a prescribed direction is formed on a light-emission surface of molding resin of the package.

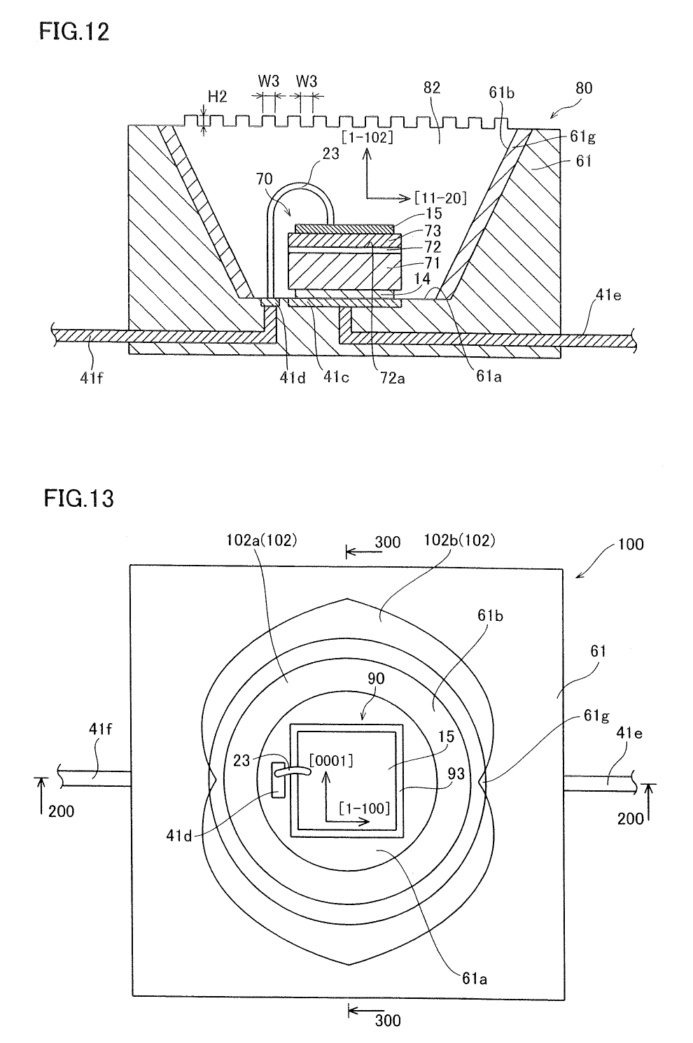

The light-emitting diode apparatus according to the fourth embodiment includes one light-emitting diode chip 70 and a package 80 in which the one light-emitting diode chip 70 is arranged, as shown in FIG. 12.

The light-emitting diode chip 70 is constituted by a wurtzite structure nitride-based semiconductor having a (1-102) plane as a principal plane. In the light-emitting diode chip 70, an emission layer 72 consisting of an MQW formed by stacking well layers (not shown) of Ga_{0.7}In_{0.3}N having a thickness of about 2 nm and barrier layers (not shown) of Ga_{0.9}In_{0.1}N is formed on an n-type GaN layer 71. A p-type GaN layer 73 is formed on the emission layer 72. An n-side electrode 14 is formed on a lower surface of the n-type GaN layer 71 and a light-transmitting p-side electrode 15 is formed on the p-type GaN layer 73 similarly to the aforementioned first embodiment.

According to the fourth embodiment, the luminous intensity of primary light emitted from the emission layer 72 has anisotropy relative to the in-plane azimuth angle of a principal plane (upper surface) 72a of the emission layer 72 similarly to the aforementioned first embodiment. In other words, as to the luminous intensity of the primary light emitted from the emission layer 72, primary light in a direction of an azimuth angle approximately perpendicular to a [11-20] direction has a larger luminous intensity than primary light in a direction of an azimuth angle parallel to the [11-20] direction.

The package 80 is constituted by a support member 61 and light-transmitting molding resin 82 similarly to the aforementioned third embodiment. The molding resin 82 is an example of the “light-transmitting member” in the present invention.

According to the fourth embodiment, a light-emission surface of the molding resin 82 is formed with a corrugatedly shaped portion. More specifically, recess portions and projection portions of the corrugated shape of the light-emission surface of the molding resin 82 each are so formed as to have a width W3 of about 2.5 μm and a height H2 of about 2 μm. The recess portions and the projection portions of the corrugated shape of the molding resin 82 are so formed as to extend in a direction perpendicular to the [11-20] direction and a [−1-120] direction. Therefore, the amount of primary light emitted in the direction of the azimuth angle parallel to the [11-20] direction among primary light emitted from the light-emitting diode chip 70 can be increased. Thus, difference in the luminous intensity of secondary light emitted from the package 80 according to variation in the in-plane azimuth angle of a chip-arrangement surface 61a of a support member 61 can be reduced, in a case where the primary light emitted from the emission layer 72 has a small luminous intensity in a direction of an azimuth angle of the [11-20] direction.

For a reason similar to that of the aforementioned third embodiment, the recess portions and the projection portions of the corrugated shape of the molding resin 82 each may have a size similar to or larger than an emission wavelength. In a case where the emission wavelength is about 500 nm, a width W3 of each recess portion is preferably not less than about 250 nm for example.

The remaining structure of the fourth embodiment is similar to that of the aforementioned third embodiment.

The remaining effects of the fourth embodiment is similar to those of the aforementioned third embodiment.

The light-emission surface of the molding resin is formed with the corrugatedly shaped portion extending in the prescribed direction so as to reduce the difference in the intensity of the secondary light emitted from the package 80 according to variation in the in-plane azimuth angle of the chip-arrangement surface 61a in the fourth embodiment, the present invention is not restricted to this but an alternate may be employed so far as anisotropic structure relative to the in-plane direction of the chip-arrangement surface is formed on the light-emission surface of the molding resin 82. In other words, the anisotropic structure has a shape in which shapes along the [11-20] direction and the direction perpendicular to the [11-20] direction respectively are different, and projection portions or recess portions each formed in an elliptical shape as viewed from an upper surface may be formed on the light-emission surface, for example.

While the light-transmitting member of the light-emission surface is constituted by the molding resin in the fourth embodiment, the present invention is not restricted to this but the light-transmitting member may be constituted by an inorganic material such as TiO₂, Nb₂O₅, Ta₂O₅, ZrO₂ and ZnO, or an organic-inorganic hybrid material of the inorganic material and an organic material.

According to the fourth embodiment, so far as the light-emitting diode chip 70 is formed such that a direction having the largest luminous intensity and a direction having the smallest luminous intensity relative to the azimuth angles of the in-plane of the principal plane of the light-emitting diode chip 70 can be distinguished similarly to the modification of the first embodiment, the direction having the largest luminous intensity of the light-emitting diode chip 70 and a direction of the corrugated shape of the molding resin can be easily matched with each other.

### Fifth Embodiment

Referring to FIGS. 13 to 16, in a light-emitting diode apparatus according to a fifth embodiment, as a shape of an anisotropic package relative to an in-plane direction of an emission layer, a light-emission surface of molding resin (lens portion) of a package is so formed as to deflect primary light toward a direction of an azimuth angle having a small luminous intensity in order to reduce difference in the intensity of secondary light emitted from the package according to variation in the in-plane azimuth angle of a chip-arrangement surface, dissimilarly to the light-emitting diode apparatus according to the aforementioned fourth embodiment. More specifically, the light-emission surface of the package is formed in a shape in which a plurality of curved convex surfaces are in contact with each other so as to form concave shapes.

The light-emitting diode apparatus according to the fifth embodiment includes one light-emitting diode chip 90 and a package 100 in which the one light-emitting diode chip 90 is arranged, as shown in FIG. 13.

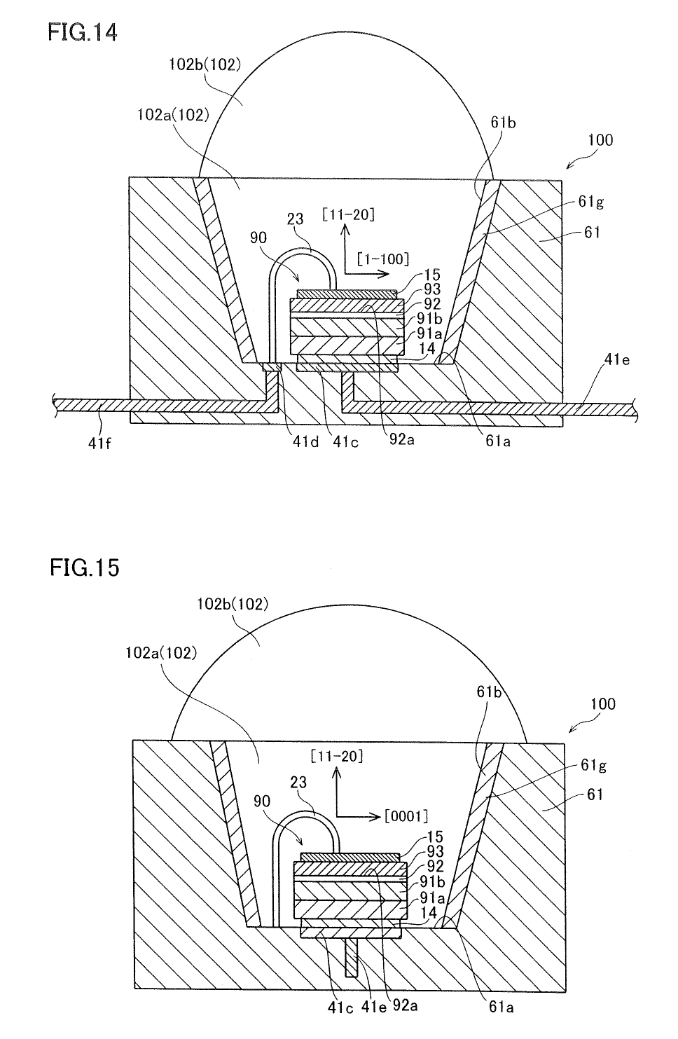

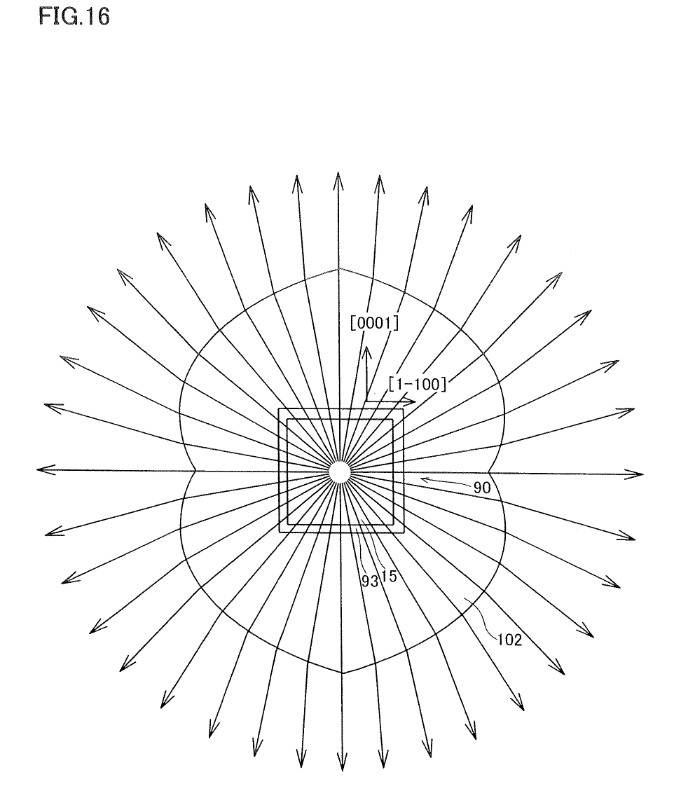

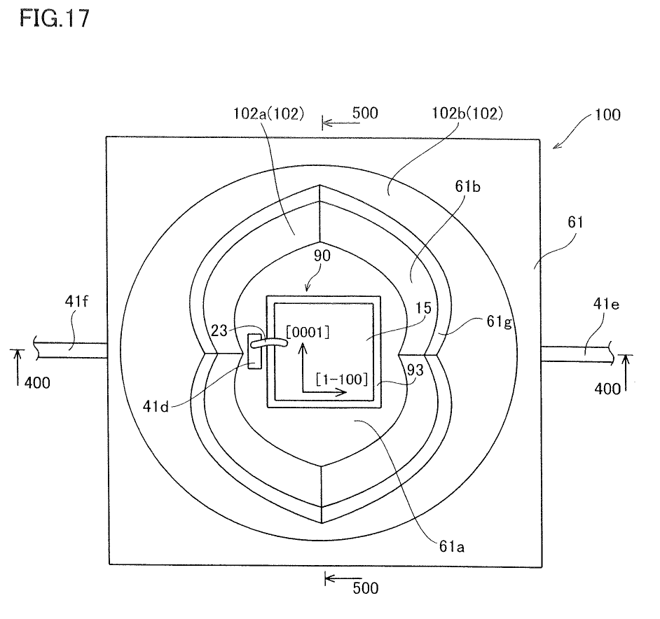

The light-emitting diode chip 90 is constituted by a wurtzite structure nitride-based semiconductor having a (11-20) plane as a principal plane as shown in FIGS. 14 and 15. In the light-emitting diode chip 90, an n-type cladding layer 91b of Al_{0.07}Ga_{0.93}N is formed on an n-type GaN layer 91a. An emission layer 92 consisting of an MQW formed by stacking well layers (not shown) of Al_{0.02}Ga_{0.98}N having a thickness of about 2 nm and barrier layers (not shown) of Al_{0.07}Ga_{0.93}N is formed on the cladding layer 91b. A p-type contact layer 93 of Al_{0.07}Ga_{0.93}N is formed on the emission layer 92. This contact layer 93 further has a function as the cladding layer. An n-side electrode 14 is formed on a lower surface of the n-type GaN layer 91a and a light-transmitting p-side electrode 15 is formed on the contact layer 93 similarly to the aforementioned first embodiment.

According to the fifth embodiment, the luminous intensity of primary light emitted from the emission layer 92 has anisotropy relative to the in-plane azimuth angle of a principal plane (upper surface) 92a of the emission layer 92. In other words, as to the luminous intensity of the primary light emitted from the emission layer 92, primary light in a direction of an azimuth angle approximately parallel to a [1-100] direction has a larger luminous intensity than primary light in a direction of an azimuth angle parallel to a [0001] direction.

The package 100 is constituted by a support member 61 and a light-transmitting molding resin 102 similarly to the aforementioned fourth embodiment. The molding resin 102 is formed by a filled portion 102a filled in an recess portion of the support member 61 and a lens portion 102b arranged on the outside of the support member 61. The filled portion 102a and the lens portion 102b each may be formed by an inorganic material such as glass, an organic-inorganic hybrid material or the like without being restricted to resin.

According to the fifth embodiment, the lens portion 102b is constituted by four convex surfaces as shown in FIGS. 13 to 15. Each convex surface is in contact with the adjacent convex surface in the azimuth angles of the direction and a [000-1] direction of the light-emitting diode chip 90 so as to form convex shapes. Each convex surface is in contact with the adjacent convex surface in the azimuth angles of the [1-100] direction and a [−1100] direction of the light-emitting diode chip 90 each having a large luminous intensity so as to form concave shapes. Therefore, secondary light emitted from the lens portion 102b (package 100) is emitted in a state of being refracted toward the directions of the azimuth angles of the [0001] direction and the [000-1] direction as shown in FIG. 16. Thus, the primary light emitted from the emission layer 92 is deflected toward the [0001] direction and the [000-1] direction each having a small luminous intensity in a case where the primary light emitted from the emission layer 92 has a small luminous intensity in the directions of the azimuth angles of the direction and the [000-1] direction, and hence difference in the luminous intensity of the secondary light emitted from the package 100 according to variation in the in-plane azimuth angle of the chip-arrangement surface 61a of the support member 61 can be reduced.

The remaining structure of the fifth embodiment is similar to that of the aforementioned fourth embodiment.

The remaining effects of the fifth embodiment is similar to those of the aforementioned fourth embodiment.

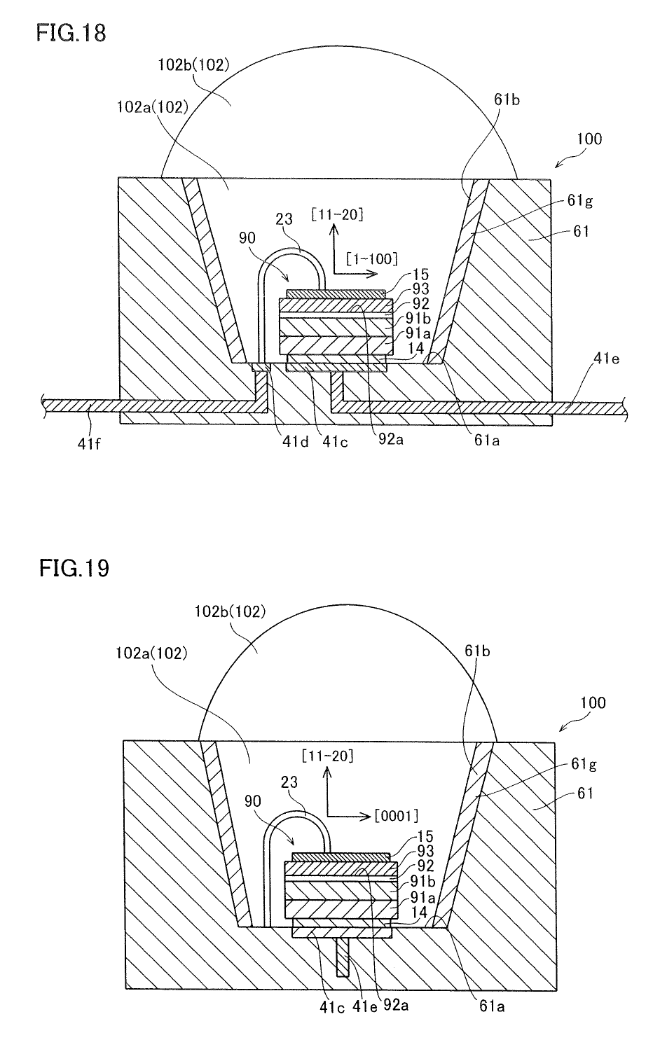

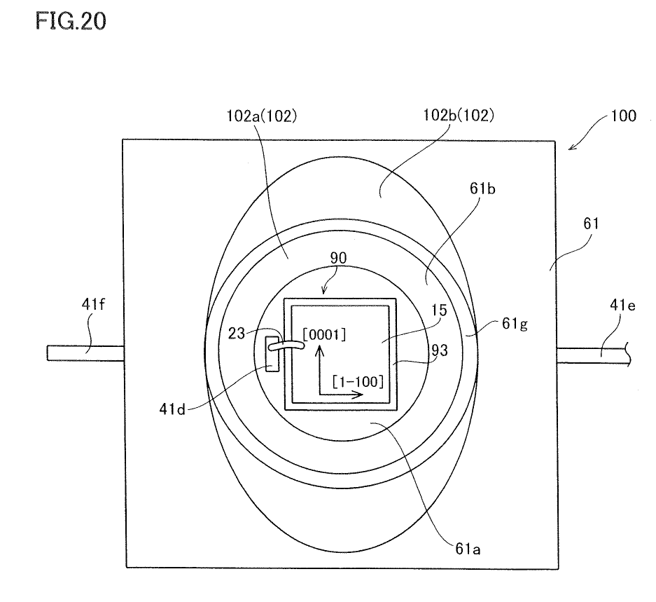

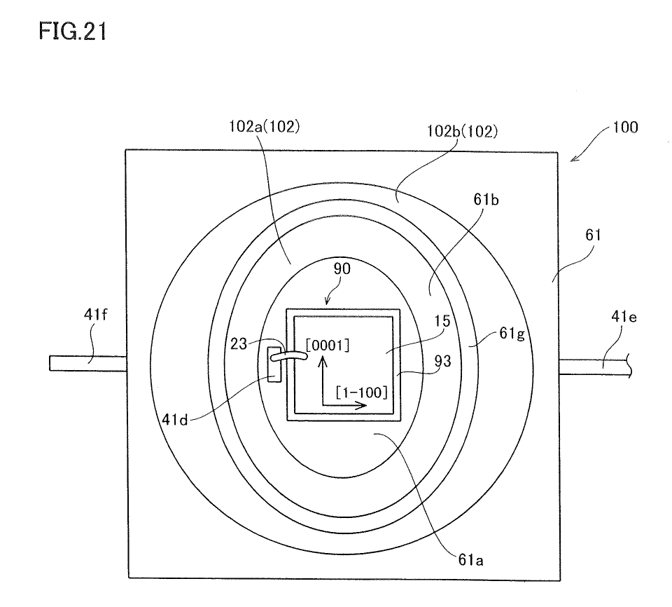

The light-emission surface of the molding resin 102 (lens portion 102b) of the package 100 is formed with the shape in which the plurality of curved convex surfaces are in contact with each other to form the concave shapes so as to reduce the difference in the intensity of the secondary light emitted from the package 100 according to the variation in the in-plane azimuth angle of the chip-arrangement surface 61a in the fifth embodiment, the present invention is not restricted to this but the reflective side surface of the package 100 may be alternatively formed with a shape in which a plurality of curved concave surfaces are in contact with each other to form convex shapes in the directions of the azimuth angles each having a large luminous intensity of the light-emitting diode chip 90 as in a first modification of the fifth embodiment shown in FIG. 17 so as to reduce the difference in the intensity of the secondary light emitted from the package 100 according to the variation in the in-plane azimuth angle of the chip-arrangement surface 61a. FIG. 18 is a sectional view taken along the line 400-400 in FIG. 17, and FIG. 19 is a sectional view taken along the line 500-500 in FIG. 17. The molding resin 102 may be formed such that a section thereof parallel to the emission layer 92 is in the form of an ellipse shape and the light-emitting diode chip 90 may be arranged such that a major axis of the ellipse substantially coincides with a direction of an azimuth angle having the smallest luminous intensity of primary light emitted from the emission layer 92 as in a second modification of the fifth embodiment shown in FIG. 20, in place of the light-emission surface of the molding resin 102 formed with the shape in which the plurality of curved convex surfaces are in contact with each other so as to form the concave shapes. Additionally, the reflective side surface of the package 100 may be formed with such a shape that the section thereof parallel to the emission layer 92 is in the form of an ellipse shape and the light-emitting diode chip 90 may be arranged such that a major axis of the ellipse substantially coincides with a direction of an azimuth angle having the smallest luminous intensity of light emitted from the emission layer 92 as in a third modification of the fifth embodiment shown in FIG. 21, in place of the reflective side surface of the package 100 having the shape in which the plurality of curved concave surfaces are in contact with each other so as to form the convex shapes.

According to the fifth embodiment, so far as the light-emitting diode chip 90 is formed such that a direction having the largest luminous intensity and a direction having the smallest luminous intensity relative to the in-plane azimuth angles of the principal plane of the light-emitting diode chip 90 can be distinguished as shown in FIGS. 17, 20 and 21 similarly to the modification of the aforementioned first embodiment, the direction having the largest luminous intensity of the light-emitting diode chip 90 and a direction of the curved convex surface of the molding resin can be easily matched with each other.

Although the present invention has been described and illustrated in detail, it is clearly understood that the same is by way of illustration and example only and is not to be taken by way of limitation, the spirit and scope of the present invention being limited only by the terms of the appended claims.

For example, while the difference in the intensity of the light emitted from the package according to the variation in the in-plane azimuth angle of the chip-arrangement surface is reduced by forming the package or the light-emitting diode chip in the prescribed shape in a case of the one light-emitting diode chip in each of the aforementioned second to fifth embodiments, the present invention is not restricted to this but the difference in intensity of the light emitted from the package according to the variation in the in-plane azimuth angle of the chip-arrangement surface may be reduced by forming both the package and the light-emitting diode chip in prescribed shapes respectively in the case of the one light-emitting diode chip. In the case of a plurality of the light-emitting diode chips, the light-emitting diode chips may be formed such that a direction of each first light-emitting diode chip and a direction of each second light-emitting diode chip intersect with each other as in the aforementioned first embodiment, while forming at least either the package or each light-emitting diode chip in a prescribed shape as in each of the aforementioned second to fifth embodiments.

What is claimed is:

1. A light-emitting diode apparatus comprising:
a light-emitting diode chip including an emission layer having a principal plane; and
a package having a chip-arrangement surface on which said light-emitting diode chip is arranged, wherein
primary light emitted from said principal plane of said emission layer has a plurality of unequal luminous intensities depending on the in-plane azimuth angle of said principal plane of said emission layer, and
at least one of said light-emitting diode chip and said package has a structure of reducing difference in the intensity of secondary light emitted from said package according to variation in the in-plane azimuth angle of said chip-arrangement surface.

2. The light-emitting diode apparatus according to claim 1, wherein
said package is formed in a structure reducing said difference.

3. The light-emitting diode apparatus according to claim 2, wherein
said package includes a reflective surface and a surface of said reflective surface has a corrugated shape.

4. The light-emitting diode apparatus according to claim 3, wherein
the interval between projection portions of said corrugated shape has a size similar to or larger than the wavelength of said primary light.

5. The light-emitting diode apparatus according to claim 3, wherein
said package includes a support member having a recess portion, and
said reflective surface is formed by forming a surface of said recess portion in said corrugated shape and forming a reflective material on said surface of said recess portion.

6. The light-emitting diode apparatus according to claim 2, wherein
anisotropic structure relative to the in-plane direction of said chip-arrangement surface is formed on a light-emission surface of said package, thereby reducing said difference.

7. The light-emitting diode apparatus according to claim 6, wherein
said light-emission surface of said package consists of a light-transmitting member.

8. The light-emitting diode apparatus according to claim 6 wherein
said anisotropic structure has a shape in which shapes along a first direction and a second direction intersecting with said first direction respectively are different in the in-plane direction of said light-emission surface of said package, and said primary light emitted in said first direction and said primary light emitted in said second direction have unequal luminous intensities with respect to the respective in-plane azimuth angles of said principal plane of said emission layer.

9. The light-emitting diode apparatus according to claim 6, wherein
said light-emission surface of said package has a corrugated shape.

10. The light-emitting diode apparatus according to claim 6, wherein
said light-emission surface of said package is so arranged as to substantially perpendicularly extend with respect to said primary light emitted from said principal plane of said emission layer.

11. The light-emitting diode apparatus according to claim 2, wherein
said package includes a lens portion through which said primary light is transmitted, and
said lens portion has a structure in which said primary light is deflected toward the direction of the in-plane azimuth angle of said chip-arrangement surface.

12. The light-emitting diode apparatus according to claim 1, wherein
said light-emitting diode chip has a light-emission surface, and
anisotropic structure relative to the in-plane direction of said light-emission surface is formed on said light-emission surface of said light-emitting diode chip, thereby reducing said difference.

13. The light-emitting diode apparatus according to claim 12, wherein
said anisotropic structure has a shape in which shapes along a first direction and a second direction intersecting with said first direction respectively are different in the in-plane direction of said light-emission surface, and said primary light emitted in said first direction and said primary light emitted in said second direction have unequal luminous intensities with respect to the respective in-plane azimuth angles of said principal plane of said emission layer.

14. The light-emitting diode apparatus according to claim 13, further comprising a semiconductor layer formed on a surface of said emission layer, wherein
said anisotropic structure is formed in a corrugated shape formed on said light-emission surface of said semiconductor layer.

15. The light-emitting diode apparatus according to claim 14, wherein
recess portions and projection portions of said corrugated shape formed on said light-emission surface of said emission layer are so formed as to extend in said second direction.

16. The light-emitting diode apparatus according to claim 14, wherein
an interval between said projection portions of the corrugated shape formed on said light-emission surface of said semiconductor layer has a size similar to or larger than the wavelength of said primary light.

17. The light-emitting diode apparatus according to claim 1, wherein
said light-emitting diode chip includes a first light-emitting diode chip and a second light-emitting diode chip, and
said first light-emitting diode chip and said second light-emitting diode chip are arranged such that a direction of an azimuth angle having a large luminous intensity in the in-plane direction of said principal plane of said emission layer of said first light-emitting diode chip and a direction of an azimuth angle having a large luminous intensity in the in-plane direction of said principal plane of said emission layer of said second light-emitting diode chip are directed to different directions from each other in the in-plane of said chip-arrangement surface of said package, thereby reducing said difference.

18. The light-emitting diode apparatus according to claim 17, wherein
the direction of the azimuth angle having the large luminous intensity in the in-plane direction of said principal plane of said emission layer of said first light-emitting diode chip and the direction of the azimuth angle having the large luminous intensity in the in-plane direction of said principal plane of said emission layer of said second light-emitting diode chip are substantially perpendicular to each other.

19. The light-emitting diode apparatus according to claim 1, wherein
said emission layer consists of either a semiconductor having a wurtzite structure or a —SiC, and said principal plane of said emission layer includes a plane other than a (0001) plane.

20. The light-emitting diode apparatus according to claim 19, wherein
said principal plane of said emission layer substantially includes a (H,K,−H−K,0) plane (H and K are integers, and at least one of H and K is not 0).

21. The light-emitting diode apparatus according to claim 1, wherein
an oscillator strength of said emission layer with respect to linear polarization of the in-plane direction of said principal plane of said emission layer has a plurality of unequal magnitudes depending on the in-plane azimuth angle of said principal plane of said emission layer.

22. The light-emitting diode apparatus according to claim 1, wherein
appearance of said light-emitting diode chip is formed such that a direction having the largest luminous intensity and a direction having the smallest luminous intensity relative to the in-plane azimuth angles of said light-emitting diode chip can be distinguished.

23. The light-emitting diode apparatus according to claim 22, wherein
an outer shape of an upper surface of said light-emitting diode chip is substantially formed in a rectangle and a long side or a short side of the rectangle substantially coincides with the direction having the largest luminous intensity relative to said in-plane azimuth angle.
